(19) United States
(12) Patent Application Publication
(10) Pub. No.: US 2010/0163283 A1
(43) Pub. Date: Jul. 1, 2010

(54) ELECTRONIC CIRCUITRY INTEGRATED IN FABRICS

(76) Inventors: Mahiar Hamedi, Linkoping (SE); Olle Inganäs, Linkoping (SE); Maria Asplund, Stockholm (SE); Robert Forchheimer, Linkoping (SE)

Correspondence Address: HOWARD & HOWARD ATTORNEYS PLLC, 450 West Fourth Street, Royal Oak, MI, 48067, US

(21) Appl. No.: 12/516,664

(22) PCT Filed: Nov. 28, 2007
(86) PCT No.: PCT/SE2007/001056

§ 371 Date: Mar. 3, 2010

(30) Foreign Application Priority Data
Nov. 29, 2006 (SE) 0602612-4

(51) Int. Cl. H05K 1/00; H05K 3/12; H05K 3/20; H05K 3/10

(52) U.S. Cl. 174/254; 427/98.4; 156/148

(57) ABSTRACT

The following invention discloses a type of electronic circuits that is realized directly on textile. The circuit has opto-electronic functions that are realized with a number of components integrated into the textile. These components comprise electronically and/or optically active material, that are supported by fabric elements. The components furthermore include an electrolyte. The components have lest two separated structures of an active material, and the electrolyte is in direct contact with the two separated active structures in that component. The separated structures can control their electrical and optical character through the electrolyte. These types of devices are very suitable for implementation in textile, since they are quite insensitive to the spacing between the separated active structures.

### TECHNICAL FIELD

The present invention relates to realization of electronics circuits integrated in fabric. The electronics components further comprise electrical and/or optical functions that require the presence of electrolytes.

### BACKGROUND ART

Integration of electronic functions within fabrics, with production methods fully compatible with textiles, is of current interest, in order to enhance the performance and extend the functions of textiles.

Most of the demonstrated prototypes of functional e-textiles are today based on the approach of integration of conventional electric components into clothes. True integration of electronics materials into textiles is however a necessary route for the realization of future e-textiles. Properties of conjugated/conducting polymers (CPs), as compared to their inorganic counterparts, include high elasticity, mechanical flexibility, and an unlimited number of chemical synthesis and processing possibilities which allows for a natural integration of CPs into fabrics. They could allow truly multifunctional electronic integration into textile. Numerous examples of passive all organic conductive fabrics have been demonstrated where a number of CPs, such as poly(3,4-ethylenedioxythiophene), polyaniline and polypyrrole (U.S. Pat. No. 5,030,508), have been coated or polymerized onto textile fibres.

One of the main challenges of electro active polymer based e-textile is the realization of textile fibres with endowed electronic functions, referred to as fibre electronics. The realization of polymer based single fibre electronic components opens the way for true incorporation of electronic functions within a textile fabric allowing for low cost, large area e-textiles. Although a conceptual description of realizing components in fabric has been described (US2005081913) no concrete solutions are given on how to realize and integrate components into textile, so that the components can be realized by using conventional fabric techniques.

Electrolyte gated components are attractive solution for the realization of active electronic components integrated in fabric. Some of these components include:
The light emitting electrochemical cell (papers: Q. Pei, G. Yu, C. Zhang, Y. Yang, A. J. Heeger, Science 269, 1086 (1995), Patents: U.S. Pat. No. 5,677,546).
The electrochemical organic transistor (patents US2006202289, US2004211989, WO02071505, Papers: Nilsson, D., M. X. Chen, et al. (2002). “Bi-stable and dynamic current modulation in electrochemical organic transistors.” Advanced Materials 14(1): 51-54. Nilsson, D., N. Robinson, et al. (2005). “Electrochemical logic circuits.” Advanced Materials 17(3): 353-+.)
the electrolyte gated field effect transistor, (Polymer field-effect transistor gated via a poly(styrenesulfonic acid) thin film, Applied Physics Letters, 2006, 89(14), 143507 Elias Said, Xavier Crispin, Lars Herlogsson, Sami Elhag, Nathaniel D. Robinson, Magnus Berggren. M. J. Panzer and C. D. Frisbie, Adv. Funct. Mater. 16, 1051 _{—}2006)

### SUMMARY OF INVENTION

The number of potential applications for multi functional fabrics or electronic textile (e-textile) is tremendous, and e-textiles could open new avenues of development in a number of areas such as bio-monitoring, tissue engineering, neural engineering, wearable communication systems, wearable computing, ergonomics etc. Although most of the demonstrated prototypes of functional e-textiles are today based on the approach of integration of conventional electric components into clothes, only true integration of electronics materials into textiles can realize real cheap integrated e-textiles. Integration of electronics into textile must include a method that is compatible with already established methods of constructing textile such as weaving, wherein the patterns that are formed are a part of the e-textile.

While present day electronics is using the field effect transistor, both this and bipolar transistors have been implemented in planar technology. Indeed the difficulties of moving the conventional field effect device onto a textile fibre are very large, if not insurmountable. Conventional organic field effect transistors (OFETs) suffer from a number of serious drawbacks, including the sensitivity to the gate insulator thickness and the large operation voltages, which prevents them from safely being incorporated into e-textile, the need for using metals as fibre core, and the need for μ-patterning along each individual fibre, through masking and evaporation steps. In general OFETs that are directly patterned on fibres are not expected to ever rival planar devices in performance.

Furthermore fibre electronics components should comprise material that are soft and can tolerate the bending and stretching of textiles, without loosing function. This will not be compatible with the requirements of a well defined insulator.

Alternative material and devices are therefore in demand to create real fibre electronics/textile electronics.

Organic conductive materials are interesting candidates as materials for fibre electronics. Some of the advantages of organic electronics materials, and especially conjugated/conducting polymers (CPs) as compared to their inorganic counterparts, include high elasticity, mechanical flexibility, and an unlimited number of chemical synthesis and processing possibilities which allows for a natural integration of CPs into fabrics. By integrating organic electronic materials into or onto monofilament, it is possible to directly create a fabric from the active monofilaments.

Electrolyte gated devices are attractive solution for the realization of active electronic components on individual fibres. Electrolyte gated components are not sensitive to gate insulator thickness, as compared to conventional FETs, and furthermore they are not constrained to work with only planar devices, since the operation of electrolyte gated devices is only dependent on the interface between an electrolyte and an active material. Electrolyte gated components also function at low operation voltages, as compared to conventional organic FETs that have high operation voltages.

The following invention discloses a type of electronic circuits that is realized directly on textile. The circuit has opto-electronic functions that are realized with a number of components integrated into the textile.

These components comprise electro-active material, that are supported by fabric elements. The fabric elements can include filled fibers, hollow fibers, filaments, mono filament, fibre bundles yarns, or combinations thereof, having materials such as polyester, polyamide, cotton or combinations thereof.

The fabric elements can also comprise metallic fibres, such as gold and silver fibres.

The components furthermore include an electrolyte that is capable of conducting ions only. The components have at least two separated structures of an electro-active material, and the electrolyte is in direct contact, with the two separated electro-active structures in that component.

The separated structures can express their electrical and/or optical character through ion conduction in the electrolyte. These types of devices are very suitable for implementation in textile, since they are quite insensitive to the spacing between the separated electro-active structures.

The electro-active material of present invention can include semi-conducting inorganic material, semi-conducting organic material, conducting inorganic material, conducting organic material, optoelectronic organic material, electrochemical organic material or possible combinations.

The electro-active materials could be placed on fibres and fabrics in processes such as solution coating, vaporizing, electro polymerizing, chemically polymerizing, forming structures such as a thin film covering the outer parts of fabric elements, or a bulk structure filling the void of a said hollow fabrics element, such as a hollow fibre or other structures.

The fabric structure of the circuitry can be constructed by arranging and forming a plurality of fabric elements, such as fibres, using conventional textile techniques such as weaving, knitting, crocheting, knotting, stitching.

Textile elements can already support the electro-active material prior to being patterned in for example weaves. In this way it is possible to construct separated junctions between fibres in a weave, where the fibres can for example contain a thin film of an electro-active material.

The electrolyte that is included in the components of present inventions can connect separated structures that lie on the same fibre by coating the fibre, or it can connect two structures on different fabric elements by being placed in-between the fibres.

The electrolyte can be placed onto the fabric using methods such as patterning from solution, or inkjet printing, or screen printing or mechanical patterning through nozzle(s), whereupon the solution could self assemble on parts of the textile according to the shape or material of the textile It is also possible to have the electrolyte supported by fibres that are directly weaved into the structure.

The electronic circuitry disclosed could further be completed with simple circuit components such as ohmic connections between fibres, and electrical insulation in and between fibres. Ohmic connections can be formed by self assembly of a conductive material from solution form, including soluble forms of conducting polymers, solutions of silver, conducting carbon paint, and combinations thereof, where said structure can include drop like formation at junctions of fabric elements, or formation of drops shapes along a fibre element.

Electronic circuitry could also be completed with resistor components, where the resistor components comprises a limited length of a fabrics element that supports a continuous conductive material, including metals or conducting organic polymers.

The described structure of the fabric allows the integration of a class of transistors called electrolyte gated transistors, which are highly compatible with fabric/textile electronics.

One transistor device that can be implemented is an electrolyte gated field effect transistor (EFET) device, where EFET comprises at least a gate, and also a channel of an electro-active semi conducting organic material having the ability of altering its conductivity through exposure to an electric field, and said channel being in electronic contact with a source, and a drain, where said source, drain and gate all comprise conducting materials. An electrolyte structure is placed in direct contact with both channel, and gate of the transistor, interposed between them in such a way that only ions flow between said channel and said gate electrode(s). The flow of electrons between source and drain contact through said channel can be controlled in such as structure by applying a voltage to the gate electrode(s). The advantage of this device structure is that the entire semi conducting film will be controlled by the applied voltage, and that low voltages are enough for operation.

One way of integrating the described electrolyte gated field effect transistor in a fabric, is by the following steps:
First forming a fabric structure having a number of electro-active fabric elements such as mono filaments, that are coated with a semi conducting thin film, and a number of electrically insulating fabric elements crossing the electro-active fabric elements so that they form junctions with each other.
Patterning a conducting material, such as metal or conducting organic material, onto said fabric structure, in a way so that the insulating fabric elements can act as an mask masking parts of the underlying semi conducting material from being covered by the conducting material.
Patterning an electrolyte at said junctions, by patterning from solution or by weaving the electrolyte in the fabric structure.

The patterning of a conducting material now forms the gate of the transistor on the previously insulating fibre, and also creates conducting source and drain contacts on the electro-active fibre on each side of the area that was masked.

One transistor device that can be implemented is an electrochemical transistor (ECT) device. An ECT comprises at least a gate, and also a channel of an electro-active organic material having the ability of electrochemically altering its conductivity through change of redox state thereof, and said channel being in electronic contact with a source, and a drain.

The source, drain and gate contact should all be of a conducting material.

In the ECT an electrolyte structure is placed in direct contact with both the channel, and the gate, interposed between them in such a way that only ions can flow between channel and gate.

The flow of electrons between source and drain contact can be controlled by applying a voltage applied to the gate electrode(s).

One possible method of forming ECTs in a fabric comprises the steps of:
First coating fibres or fabric elements with an electronically and electrochemically electro-active material, one such material is the conducting polymer material poly ethylene(dioxy thiophene) PEDOT in different forms, such as PEDOT:PSS or PEDOT tosylate.
Secondly patterning the coated fabric elements in a fabric structure having a number of junctions between coated fabric elements, where said fabric elements in junctions are not in electronic contact
Placing ion conducting electrolyte such as a solid polymer electrolyte, at the junctions.

Another class of component that can be realized in the disclosed fabric circuitry is light emitting electrochemical cell (OLEC).

An OLEC comprises a channel consisting of an opto-electronically electro-active electrolyte, where the electrolyte is comprising of a blend of a semi conducting, luminescent, conjugated, organic polymer and an ionic species, having the ability of emitting light upon applied voltage on two side of the channel The voltage can be applied to the channel through application of voltage between an anode and a cathode of conducting materials, where anode and cathode are in contact with the channel.

A way of assembling an OLEC comprises the steps of:
1. Patterning conducting fabric elements in fabric structure, where a number of said conducting fabric elements form junctions, and where fabric elements in junctions are not in electronic contact
2. Placing a channel at the junctions, by assembling the opto-electronically electro-active electrolyte from a solution, or by placing electrolyte through weaving.

One class of component that can be realized in the disclosed inventions comprises electrochromic components. These compomemts contain material classes that are capable of changing color upon electric reactions with an electrolyte. Such materials can be found in the class of conjugated polymers such as polyethylene dioxythiophenes, polythiophenes, polyanilines, polypyrroles, or any combinations thereof.

Electrochromic components can be realized by having bundles or single monofilaments, where each fibre in a bundle could contain one or several thin films of electrochromic material. These material of these fibres are switched at the junction where they are in contact with electrolyte by applying a voltage on the other fibres that carries an electro-active material.

All the types of components that can be realized with disclosed invention comprising ECTs, EFETs, OLECs, and electrochromic cells, can be integrated together in fabric patterns, where also resistors and ohmic connections are designed in such way that they all together form integrated circuits having certain advanced functions such as multiplexers digital inverters and digital logic.

Such circuits could also comprise displays, or computers.

The fabric circuits could also be integrated with conventional electronic circuits.

### BRIEF DESCRIPTION OF THE DRAWINGS

FIG. 1 is a schematic picture of different type of fabric elements including mono filaments, hollow fibers, ribbons, yarns and bundles.

FIG. 2 is a schematic picture of different fabric elements that carry/support electro electro-active material (black).

FIG. 3 is a schematic picture of electrochromic components at junctions, where the components change color upon application of voltage.

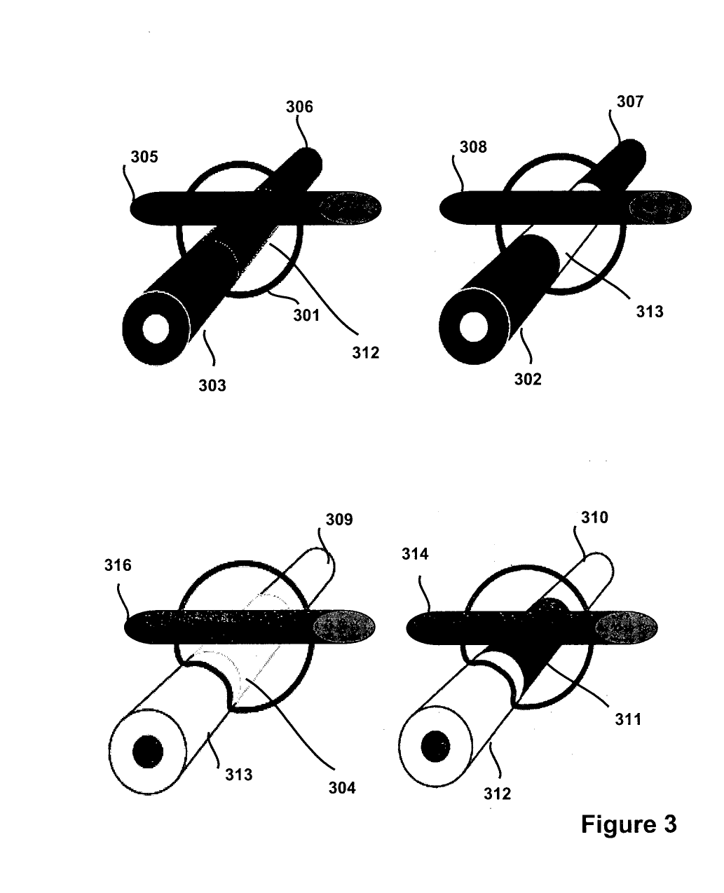

FIG. 4 is a schematic picture of patterning of electrolyte 404 at a junction, and a picture of 3 different types of components realized at junctions of fabrics elements with different character including bundles 407, monofilaments 403 and hollow fibers 401.

FIG. 5 shows schematic pictures of a components at a junction, showing electro-activity in the electro-active material supported by fibres 513, 512, and ionic activity 517 in the electrolyte connecting the junction. The components can include electrochemical transistors 517 and field effect transistors 510, 511, and light emitting cells 518

FIG. 6 show schematic pictures of weaves created with fibers that carry electro-active material (black), and regular fibers (white), where a number of components are created by patterning of electrolyte 604 at a number of junctions 609.

FIG. 7 show schematic pictures of a certain weave structure where a junction if created with one fiber running over two other fibers in a row, and the other running under two other fibers in a column, so that the fibers at the junction are separated 703, the picture further shows patterning of an electrolyte at a separated junction via two electrolyte threads 706.

FIG. 8 is a schematic picture of a method of making electronic clothes, and also shows a method of making a resistor using a length of an electro-active thread.

FIG. 9 show schematic pictures of a junction with an electrolyte showing the separation of fibers at the junction, and electrolyte joining the fibers at the junction.

FIG. 10 shows schematic pictures of a electronic circuitry that can be realized in a mesh of fabrics, by placing a number of components in a pattern on the fabric mesh.

### DETAILED DESCRIPTION

### Definitions

With the word electrolyte we mean any material that is capable of conducting ions or ionic species, including liquids containing salts, and solid polymer electrolytes that can conduct ions, or ionic liquids.

The words electro-active, opto-electronic, electro-active or active material, should all be taken to mean any material that is capable of conducting electrons, or holes, these material can also be optically active through electronic phenomenon such as exciton reactions, and also electrochemically active. Some classes of such materials include for example conducting and semi-conducting organic materials such as conjugated polymers, carbon nanotubes, and carbon balls, or conducting metals, or semi-conducting in-organic material such as silicon, or classes of InGaSP.

### Coating of Fabric Elements

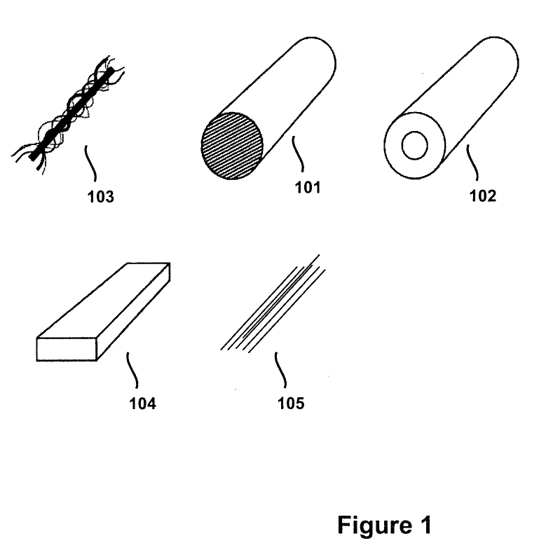

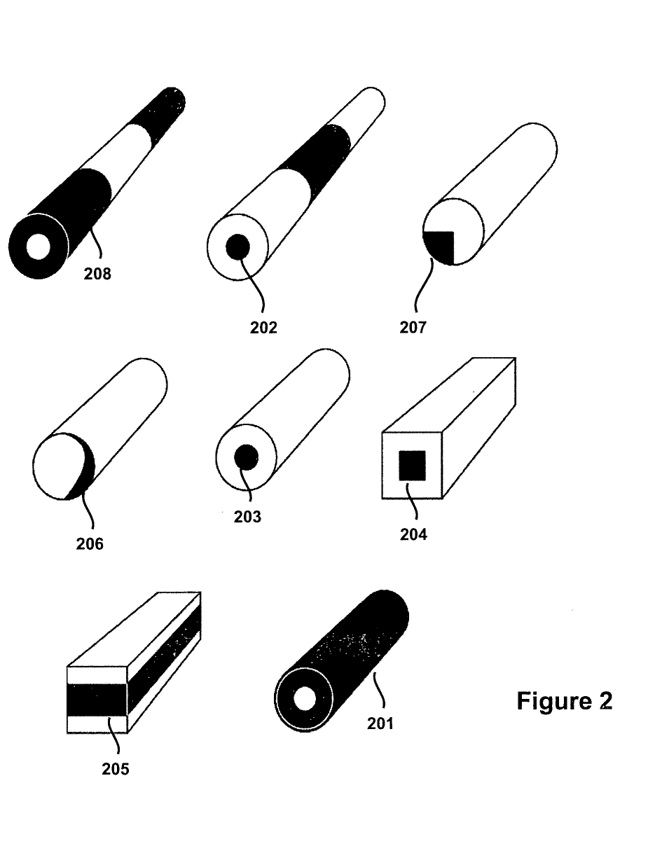

The basic elements of the circuits in this invention comprise fabric elements such as monofilaments, other types of fibre like structures that can be used for the creation of fabrics, see FIG. 1. Monofilaments can for example be coated with an electronic and electrochemically active conducting polymer layer, so that the active material is carried by the fabric elements in a number of possible configurations as displayed by FIG. 2, where the black parts display the active material. An interesting material to date is the the low bandgap conducting polymer poly(3,4-ethylenedioxythiophene) (PEDOT), for the high conductivity, water dispersibility, and environmental stability. Impregnation of polyamide textile from the aqueous solution of poly(3,4-ethylenedioxythiophene) doped with poly-(styrenesulfonate) (PEDOT/PSS), and in-situ polymerization of PEDOT on nylon 6, polyethylene tereftalate PET and PTT have previously been demonstrated. High conductivity formula of PEDOT containing by weight 95% of PEDOT/PSS (Baytron P from Bayer, Krefeld, Germany) 5% of the secondary dopant diethylene glycol, and 0.1 wt % of the surfactant Zonyl FS-300 (Chemika/Fluka) can be used for the coating of monofilaments.

Coating of fabric elements can be carried out using a flow of active conducting polymer, under the influence of gravity, or by pulling fibres out of a solution. Coating from solution is versatile and reproducible, and most of the common textile fibre materials such as polyamide, Kevlar and polyester, can be coated with fibre diameters varying from a few hundred micrometers down to 5 μm. Coating of fibres can also be carried out using chemical methods such as polymerization of electro active polymers.

### Forming Fabric Structures

The creation of fabric structure is very versatile, and different fibres of different shapes and material can be weaved in any arbitrary complex 3D structure.

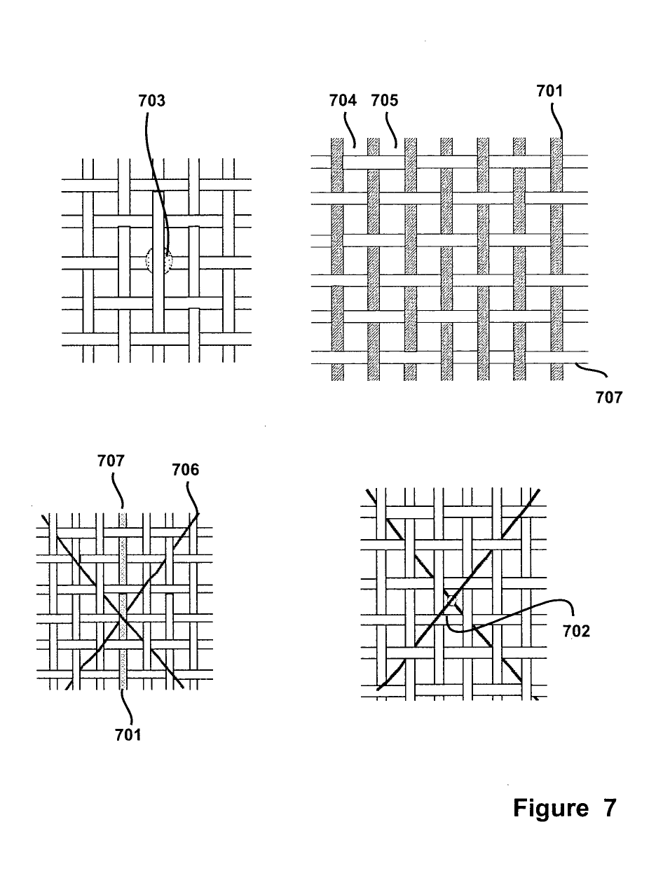

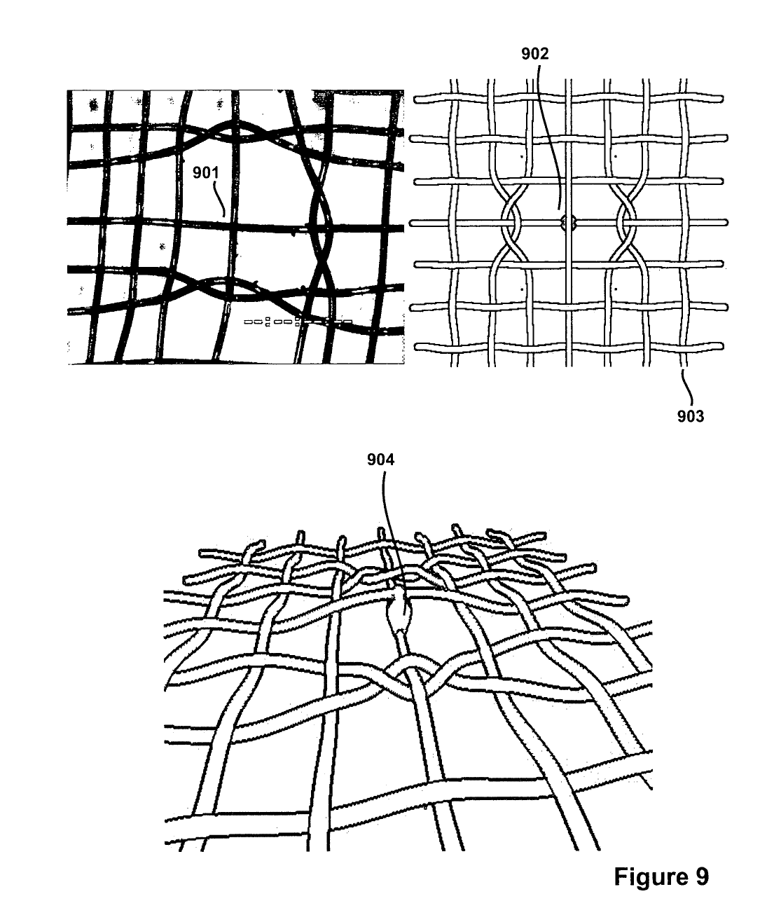

With proper coating procedure it is possible to form thin films of active material on or inside fabric elements such as monofilament or hollow fibers, and then use the coated fibres in processes such as weaving or knitting, for forming structures. It is for example possible to make 3D fabrics that include different insulating fibres, see for example FIG. 7 (701,707,706), metal fibres, and fibres coated with electro active organic/inorganic material. It is also possible to create junctions of fibres that are not in electronic contact, see for example FIG. 7 (703) and FIG. 9 (902), as these structures are particularly interesting for the realization of the components in the present invention.

Traditional weaving techniques combined with some new developed tools can be used as the main route of production. This would allow effective large-scale production of devices and also ensure that useful textile properties like flexibility, stretchability and porosity are maintained. Several different textile techniques can be applicable, and below, some examples of such are listed and explained in short.

Weaving with Loom

The most common way to produce a plain textile is to use a loom. Using the loom, the set of parallel fibres constituting the warp can be set up and subsequently bound by the perpendicular fibres, weft, that are weaved into the warp row by row. The mechanical stability comes from that the weft is weaved through alternately raised warp fibres.

### Embroidered Electronics

Through embroidery the fibre can be simply pulled through a previously prepared textile one example is seen in FIG. 9 using spacings between threads in the weave. When the fibre is sewn there is also a possibility to attach additional components slipped on the thread like pearls on a string, see FIG. 7 (702).

### Knitting Electronics

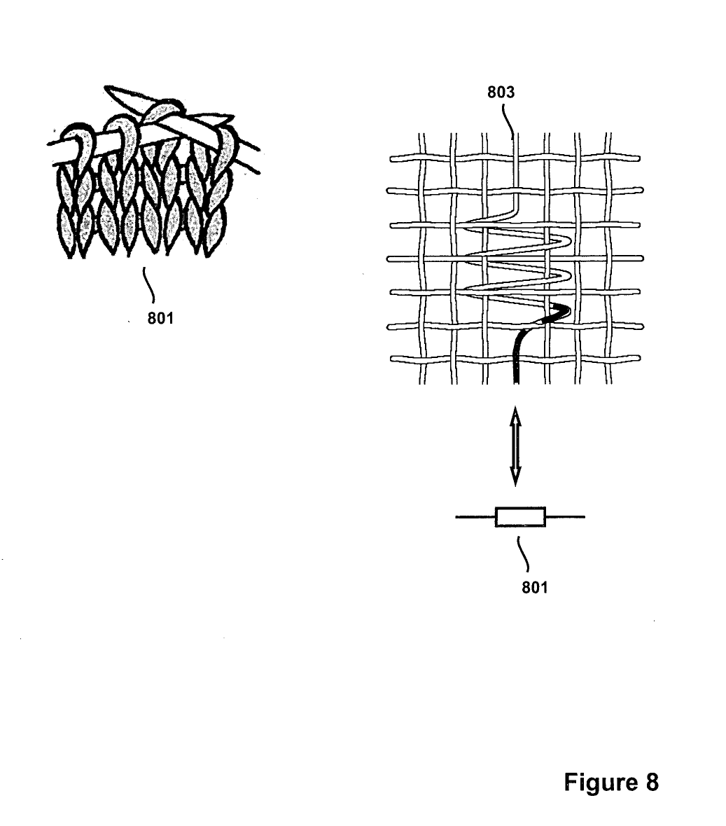

Knitting is performed using one fibre (yarn) which is worked into a line of loops, example FIG. 8 (801) that are build on row wise into a textile structure. Because of this curled structure of each row, knitted textiles are highly stretchable compared to a weaved textiles, which mainly consists of straight fibres. Knitting is commonly performed in special machines and can hence be a very effective production technique.

Bobbin Lace making

Bobbin lace technique can produce almost any type of textile structure mentioned above since all fibres can be moved around individually. This very traditional technique is based on that all thread used are attached in one end parallel to each other but on the other end is attached to loose bobbins and can further on in the weave be twisted, plated and even tied around each other freely. Since large bobbins can easily be attached to very thin threads the technique can be used to create very delicate structures with great versatility and control.

### Special Textile Structures

An important structure to realize for the implementation of our textile logic is the crossing between two fibres, either fixed in contact or separated by a small space. A crossing of two threads that are in contact with each other is easily made like any crossing in the straight weave. One way to achieve a small space between fibres in a crossing is to let the crossing fibres not bind to each other at the crossing point. The tension in the other fibres will force the crossing fibres to separate at this crossing. A drawback is that this also destabilizes the weave leading to neighbouring fibres slipping into the middle of the crossing point. Therefore a concept for preventing the weave from collapsing into the middle is suggested example FIG. 9 (903). Using this concept it is possible to create separated fibers at junction See FIG. 9 (902), in order to be able to create the components of the described invention, where electrolyte is placed at junctions, displayed in FIG. 9 (904).

As the dimensions of fibres can approach some μ meters, it is possible to realize controlled micro structures in 3 dimensions, without any step of conventional micro patterning, such as lithography.

Transistor Devices Integrated with Fabrics

The transistor is the most important device in both digital and analog electronics, and therefore of first interest, when realizing a circuitry in a weave. The types of transistors that can be realized with present invention comprise transistors that have conductive channel that is in contact with an electrolyte. Two such transistors are described in more detail.

### Electrochemical Transistors in Fabrics

The operation of an all organic electrochemical transistor (ECT) is based on a reversible process of doping/de-doping of conjugated polymers, and can be realized with all materials that can change their conductivity through redox operations.

One such common material up to date is PEDOT/PSS. Switching the conductivity of a transistor channel consisting of PEDOT/PSS is made through a reversible redox process in the following reaction PEDOT+(PSS−)+M++e− [symbol] PEDOT0(M+PSS−)

This redox processes can be achieved in electrochemical devices comprising thin films of PEDOT in contact with a common electrolyte, where the cations are supplied by the electrolyte and the electrons are transported inside the conducting polymer. Doping and de-doping of PEDOT can result in conductivity changes of up to 5 orders of magnitude. Electrochemical transistors have previously been demonstrated on flat surfaces such as glass, plastics, and paper, through patterning of the conducting polymer film followed by patterning of a second layer of electrolyte. Large scale digital logic devices, and displays have also been demonstrated by patterning a number of electrochemical transistors on flat surfaces.

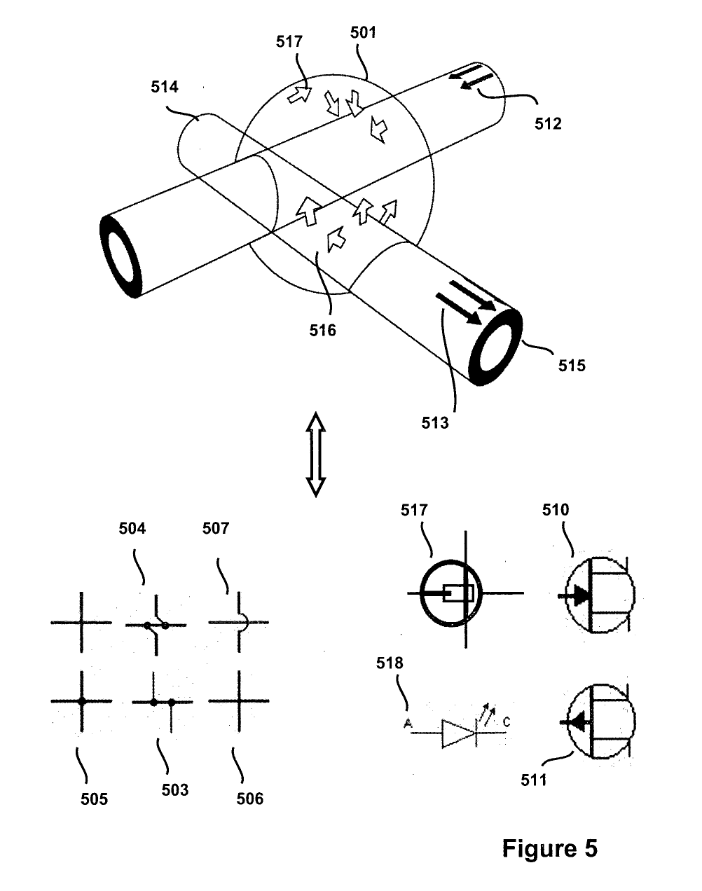

ECTs can be realized in non planar geometries, by constructing all organic Wire Electrochemical Transistors (WECTs). The WECTs were realized by crossing two PEDOT/PSS coated fibres and creating an ionic contact by adding a solid electrolyte in solution see FIG. 5, at the crossing of fibres. Surface energy help direct the fluid carrying the solid electrolyte to the crossing, and only at this junction is electrolyte located.

There are also other methods for placing the electrolyte at junction of fibres such as having the electrolyte on other fabric elements, that are weaved into the junctions, or by printing electrolyte.

The electronic measurements on WECTs show current saturation in WECTs with increasing drain voltage. The transistor is in the on state at gate voltage 0 V, and as the gate voltage is increased, the transistor channel is depleted and the transistor is turned off, with on/off ratios >500 for low gate voltages between 0 to 1.5 volts. The IV character of the ECT is similar to the solid-state p-type depletion MOSFET.

This similarity is due to the fact that the operation of the electrolyte gated transistor is dominated by the interface between the electrolyte and the conducting polymer film, where the main potential difference is located. Due to the interface dominated operation, the active part of the transistor channel comprises the entire cylindrical film which is in contact with the electrolyte. Furthermore the operation voltage is very insensitive to the distance between the gate and the channel, and the low operating voltage is between 0 to 1.5 volts, which is the electrochemical potential window of the PEDOT/PSS.

The redox conversion using a electrolyte contact operation thus solves all the serious drawbacks of conventional field effect devices operation, such as sensitivity to gate distance which make impossible the switching operation of an entire cylindrical film at micro dimensions using another fibre as gate, and the high gate voltages. As the local geometry does not have a major impact on device function, the need for precise positioning and for stability of geometry is gone. This matches the production of fabrics, and the need to make these take on many geometries and drapes.

### Electrolyte Gated Organic Field Effect Transistors (EFET)

Another class of transistors comprises electrolyte gated field effect transistors. These transistors differ from the ECT by having a gate that comprises a semi conducting material being in contact with an electrolyte. As voltage is applied on the electrolyte this transistor will be turned on due to doping of the semi conducting material based on the field distributed between electrolyte and semiconductor interface.

FIG. 5 shows such a transistor with a source 514 and drain 513 and gate contact 512 of a conducting material.

The EFET can therefore be realized similarly to the ECT, by changing the channel material of the ECT for a semi conducting material.

One possible way of constructing EFETS along fibres would be to start with fabrics having fibres that are coated entirely with semi conducting material, and other insulating fibres could form a number of junctions with the semi conducting fibre. This fabric could then be further coated with a conducting material, in a process where the insulating fibres would act as a shadow mask for the channel.

The coating of conducting material could be carried out by using for example evaporation of a metal or inorganic/organic conducting material, or by coating a solution from above.

The length of the constructed channels would be in the same dimension as the diameter of the insulating fibre, which can be as small as only some micrometers in fabrics.

Light Emitting Diodes Integrated with Fabrics

The invention of the polymer light-emitting electrochemical (OLEC) cell provides a new route to light-emitting organic devices. In these light-emitting electrochemical cells, a p-n junction diode is created in-situ through simultaneous p-type and n-type electrochemical doping on opposite sides, respectively, of a composite film of conjugated polymer (between two electrodes) which contains added ionic species (salt) to provide the necessary counterions for doping. Such polymer light-emitting electrochemical cells have been successfully fabricated with promising results. Blue, green, and orange emission have been obtained with very low turn-on voltages close to the bandgap of the emissive material.

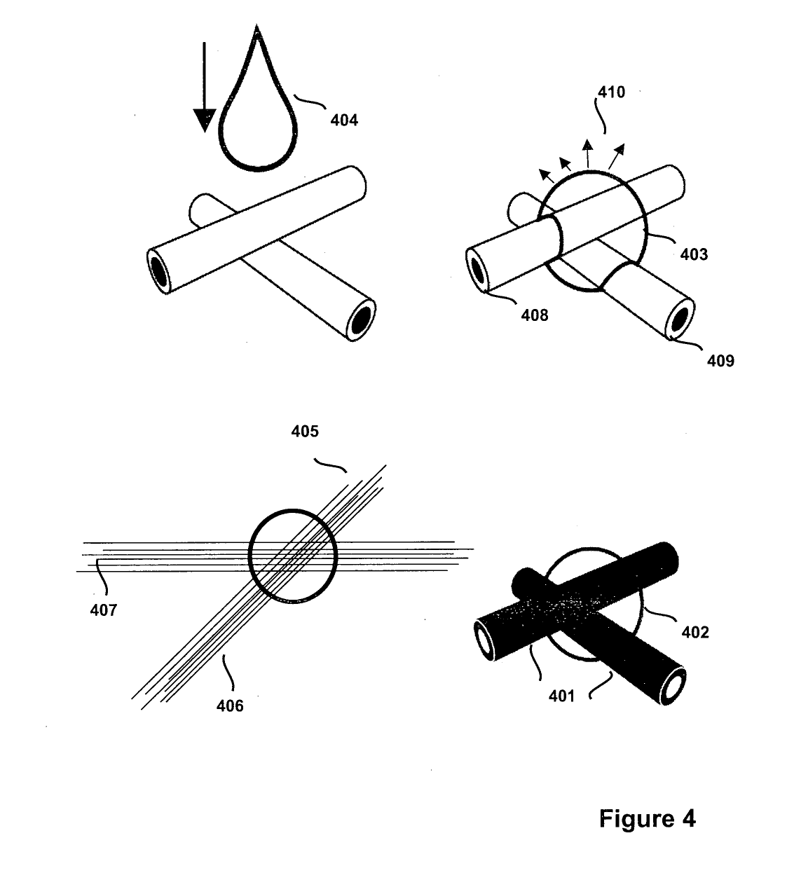

The operation of OLECs are quite insensitive to the spacing between the two electrodes, and also on the form of the active light emitting material. FIG. 4, shows an OLEC where the electrolyte is emitting light 410, and the fibre 408 and fibre 409 are used as contact points to the OLEC. It is therefore possible to realize such transistors between two conducting electrodes in a fabric. The conducting electrodes can be on the same fibre, but most probably should be on different fibres, where the OLEC could for example be realized at the junctions of the conducting fibres, with the constraint that the fibres are not in electronic contact at the junction, by patterning the active OLEC material from a solution, or by having the material on a fibre that is crossed by other conducting fibres.

By using different colours and small fibres in junctions at some 10 micro meter dimensions, pixels with any color, could be realized in a two or three dimensional mesh with sub 100 micrometer spacing between OLECs.

### Large Scale Integration of Transistors

The fabrication of the WECT and the EFET is insensitive to vertical displacement between fibres, due to the described interfacial operation of the device. Furthermore WECTs creation is also insensitive to horizontal displacement along fibres because source and drain contacts consist of the same material as the channel and the gate. The transistors are also quite insensitive to the shape or amount of the electrolyte.

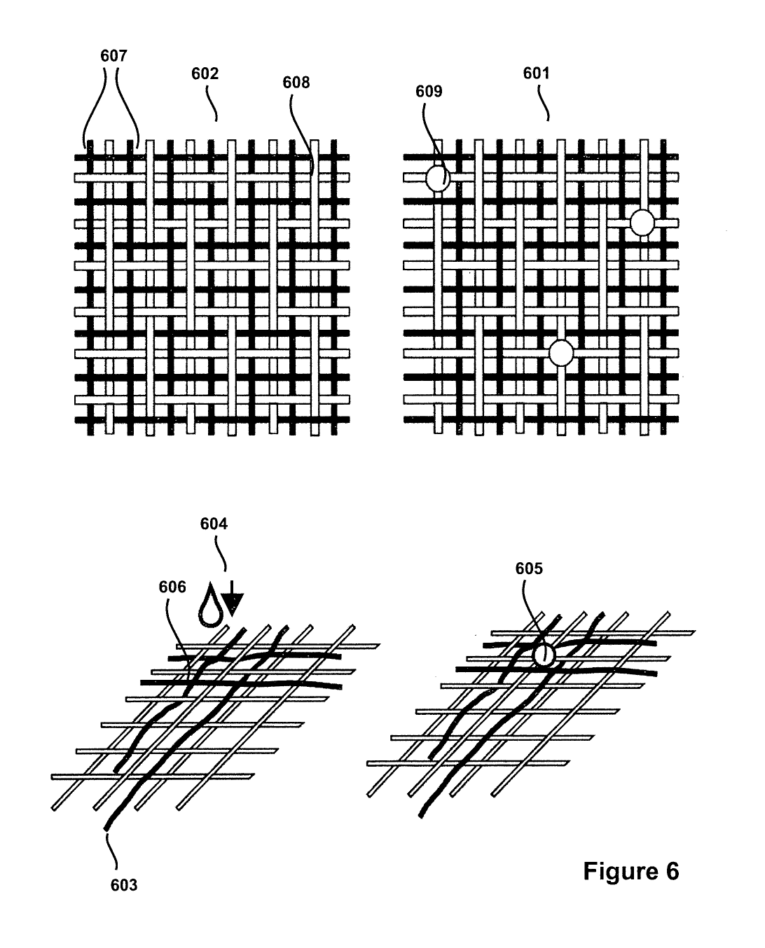

Transistors can therefore be easily constructed across any micro fibre junction in a 3 dimensional weave using self assembly of electrolyte drops, see for example FIG. 6, whera 601 represents one of many components at junctions in a weace. The fabrication of fibre transistors eliminates the need for lithography patterning steps, which are only 2 dimensional and hardly compatible or cost efficient for e-textiles. Furthermore the insensitivity of the transistor function together with the insensitivity of organic electro active materials such as polymers to bending and stretching, makes these transistors operational even if the fabric is under mechanical bending or stretching.

The transistor component can easily be completed with other less sophisticated components such as resistors or ohmic connections between different points in the fabric fibres. Ohmic connectors can for example be realized across fibre junctions by placing different fluids of conducting material at that junction.

Resistors of various size can be realized on coated monofilaments, by varying both the length of the fibres and also using materials with different conductivity values.

### Construction of Electric Circuits Using WECTS

The three dimensionality and mode of operation, makes WECTs totally symmetrical, meaning that any of the four connection points to the transistor can be chosen as a gate and any of the corresponding two connections on the other fibre can then be chosen as source and drain. It is also possible to realize many transistors along one single fibre since the channel consists of the same conducting material as the rest of the fibre. The WECT component can easily be completed with ohmic and isolating connectors for example by placing fluids of conductive polymers or insulating polymers at fibre junctions.

The symmetry and ease of construction of WECTs together with the unlimited number of possible three dimensional fabric topologies and material mixtures possibilities can be used for the realization of large scale integration of general micro electronics directly on fabrics. The demonstration of 10 μm WECTs (fig), show that it would theoretically be possible to construct at least 250,000/cm2 transistors on 2 dimensional fabrics, and the number would of course increase by taking advantage of a third dimension.

The architectural design of any general wire electronic circuit, and in general digital circuits, is just a question of design, where both the 3 dimensional design of the fabric structure and the placing of the fibre electronic components can be used in order to achieve device functionality.

### Examples

Multiplexer with WECTs

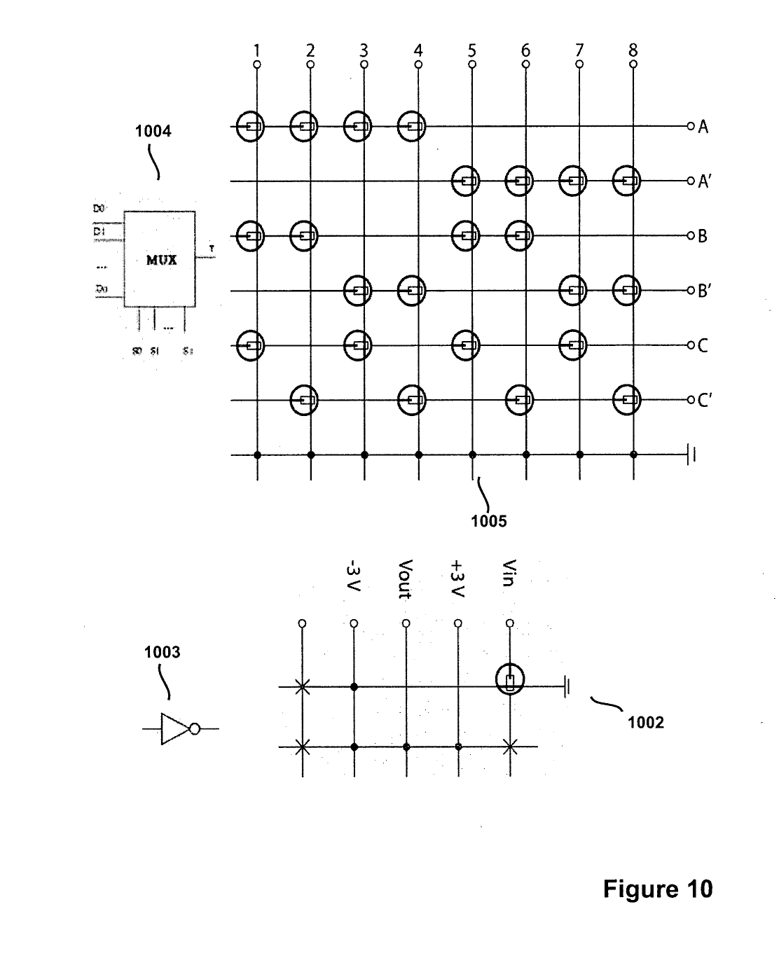

A fundamental digital electronic device is the multiplexer which enables encoding of information from a large number of data sources into a single channel. This device can be designed across a weave of fibres, by placing WECTs in a pattern that represent a binary tree multiplexer structure see for example FIG. 10 (1005).

Inverters and Logic with WECTs

The most fundamental building block of all digital electronics is the inverter, which can be used for the realization of memory, decoders, state machines, and other sophisticated digital devices. Inverters can be constructed with WECTs, and resistors alng fibres, using the class of resistor-transistor logic digital circuits. FIG. 10 (1002) shows an inverter that is realized on a fibre mesh. Realization of circuitry using electrochemical transistors has been disclosed by patents US2006202289, US2004211989, WO02071505.

### Construction of Electric Circuits Using EFETs

The construction of circuits with EFETs can be done in similar manners as the WECTs. It is possible to realize several EFETs on a fibre using the source of one transistor as the drain of its neighboring transistor on the same fibre. The mode of operation of EFETs can also be n type, and it is possible to construct more advanced logic using p-n type 510,511 mixtures of transistors

### General Construction of Fabric Circuits

All the described components can be arranged in any arbitrary 3 dimensional fabric structure, in order to form arbitrary complex three dimensional micro electronic circuits. The described invention could of course be mixed with other types of passive and active fibre components or electronics textile components.

### Active Electrochromic Displays

Electrochemical or field effect transistors could be connected to elecrtochromic components at junctions in a mesh so that each electrochromic component could be driven through a set of addressing rows and columns, and act as an active pixel to form an active matrix reflective display. The electrochromes could comprise one colour or have different colours forming monochrome respectively colour displays.

### Active Light Emitting Displays

Electrochemical or field effect transistors could be connected to OLECs at junctions in a mesh so that each OLEC could be driven through a set of addressing rows and columns, and act as active pixels to form an active matrix emission display. The OLECs could comprise one clour or have different colours forming monochrome respectively a colour displays.

General Circuits could Comprise Displays, Actuators, Sensor Arrays, Digital Computers, or Combinations.

Mixture of fabrics circuits with conventional electronics

The disclosed fabrics circuitry can of course also be connected to any other general electronic circuit being of non fabric character, such as conventional electronic circuits.

1. An electronic fabric comprising electronic components wherein each said component comprises at least two fabric elements each supporting one or more electro-active materials, and where said electro-active materials are connected in junction between said two fabric elements via an electrolyte.

2. The electronic fabric of claim 1, where said electro-active material includes semi-conducting inorganic material, semi-conducting organic material, conducting inorganic material, conducting organic material, optoelectronic organic material, electrochemical organic material or any possible combination thereof.

3. The electronic fabric of claim 1, where said fabric elements include filled fibers, hollow fibers, filaments, monofilament, fiber bundles, yarns or combinations thereof, and said fabric elements including polyester, polyamide, cotton or any possible combinations thereof.

4. The electronic fabric of claim 1, where said fabric elements comprises metallic fibres where parts of said metallic fibres have an electronic insulating layer.

5. The electronic fabric according to claim 1 wherein said electro-active material comprises one or more thin films covering the outer parts of said fabric elements, or a bulk structure filling the void of a hollow fabrics element or any combinations thereof.

6. A method of forming an electronic fabric comprising the steps of:
forming a plurality of fabric elements that can support electro-active material, in a fabric pattern using anyone of weaving, knitting, crocheting, knotting, stitching or any possible combinations thereof, wherein said fabric pattern includes junctions between fabric elements; and
forming a plurality of electrolyte structures at some or all of the junctions.

7. The electronic fabric according to claim 1 where said electro-active material is formed on said fabric elements using chemical polymerization, electrochemical polymerization, coating from liquids, evaporation or any combinations thereof.

8. The method of forming the electronic fabric according to claim 6, wherein said step of forming a plurality of electrolyte structures includes patterning said electrolyte structures from solution on parts of said fabric pattern through the methods of inkjet printing, or screen printing or mechanical patterning through nozzle(s), or any combinations thereof.

9. The method of forming the electronic fabric according to claim 6, wherein said step of forming a plurality of electrolyte structures includes the steps of disposing fusible electrolyte structures in solid form on the fabric elements and melting the fusible electrolyte structures such that electrolyte structures are self assembled on said fabric elements from a molten state, forming new structures at said fabric junctions.

10. The method of forming the electronic fabric according to claim 6, wherein said step of forming a plurality of electrolyte structures includes the step of depositing an electrolyte solution at the junctions of the fabric elements or along the fabric elements.

11. The electronic fabric according to claim 1, where parts of at least two of said electro-active materials are supported by different fabric elements, and are in ohmic contact with each other through a conductive structure.

12. The method of forming the electronic fabric according to claim 6 further comprising the step of forming at least one conductive structure by self assembly of a conductive material from solution form, including soluble forms of poly(ethylene dioxythiophene), poly aniline, poly pyrrole, solutions of silver, conducting carbon paint, or any combinations thereof, where said structure can include drop like formation at junctions of fabric elements, or formation of drops shapes along fabric elements.

13. The electronic fabric according to claim 1, where at least one of said components is connected to a resistor component formed by using two contacts separate by a limited distance on a continuous electro-active material that is supported by a fabric element.

14. The electronic fabric according to claim 1, where at least one of said components is further defined as a transistor comprising an electro-active gate material supported by one of the said two fabric elements of that component, and further comprising an electro-active channel material that is connected to a source and a drain contact, said channel material being supported by the other of said fabrics element, where part of said gate and said channel are in contact at said junction via an electrolyte, and where the resistance of said channel is controllable by means of a voltage applied to said gate.

15. The electronic fabric according to claim 14, where said channel material comprises an electro-active material capable of changing resistance upon redox reactions, including but not limited to classes of polythiophenes, poly ethylene dioxythiophenes, poly anilines, or polypyrroles, or any combinations thereof and where said gate material comprises a conducting material, or a material capable of changing resistance upon redox reactions.

16. The electronic fabric according to claim 14, where said channel material comprises a material capable of changing resistance upon the formation of an ionic double layer at the interface of the channel material and said electrolyte, and where said gate material comprises a conducting material.

17. A method of forming an electronic fabric having a plurality of transistors, comprising the steps of:
forming a fabric structure having a number of channel fabric elements that support semi conducting material, and a number of gate fabric elements crossing said fabric elements that support semi conducting material forming junctions;
patterning a conducting material onto said fabric structure, where said gate fabric elements act as an evaporation mask, masking parts of said channel fabric elements, so that no pattern of the conductive material is formed on said channel fabrics element at said junctions; and
patterning an electrolyte at said junctions

18. An electronic fabric according to claim_1 wherein at least one of said components is further defined as a light emitting chemical cell having an anode comprising a conductive material supported by one of said two fabric elements, and having a cathode comprising a conductive material supported by the other of said two fabric elements, and also having an electrolyte comprising a blend of a semi conducting, luminescent, organic polymer and an ionic species, having the ability of emitting light upon applied voltage between said anode and cathode.

21. An electronic fabric according to claim_1 wherein at least one of said components is further defined as an electrochromic cell comprising an electrochromic material supported by one of said two fabric elements, and also having a conductive material supported by the other of said two fabric elements, said electrochromic cell having the ability of changing color upon applied voltage on said conductive material.

19. An electronic fabric according to claim 1, wherein at least two of said electronic components are electrically connected together to form an electronic circuitry.

20. An electronic fabric according to claim 19, further comprising connection with a conventional electronic circuitry.
